(19) United States
(12) Patent Application Publication
(10) Pub. No.: US 2020/0152841 A1
(43) Pub. Date: May 14, 2020

(54) NANOPOROUS MICRO-LED DEVICES AND METHODS FOR MAKING

(71) Applicant: Yale University, New Haven, CT (US)

(72) Inventors: Jung Han, Woodbridge, CT (US); Chia-Feng Lin, Taichung City 412 (TW)

(73) Assignee: Yale University, New Haven, CT (US)

(21) Appl. No.: 16/632,044

(22) PCT Filed: Jul. 27, 2018
(86) PCT No.: PCT/US2018/044023

§ 371 Date: Jan. 17, 2020

Related U.S. Application Data
(60) Provisional application No. 62/538,994, filed on Jul. 31, 2017.

(51) Int. Cl. H01L 33/50; H01L 25/075; H01L 25/16; H01L 33/06; H01L 33/22; H01L 33/32; H01L 33/42; H01L 33/62; C09K 11/88

(52) U.S. Cl. CPC H01L 33/505; H01L 25/0753; H01L 25/167; H01L 33/06; H01L 33/22; H01L 33/32; B82Y 20/00; H01L 33/502; H01L 33/62; C09K 11/883; H01L 2933/0041; H01L 2933/0066; H01L 33/42

(57) ABSTRACT

The present invention provides LED devices comprising gallium nitride LED diodes, at least a portion of which have been modified with color-converting quantum dots. The invention also provides methods of fabricating the LED devices of the invention.

### CROSS-REFERENCE TO RELATED APPLICATION

This application claims the benefit of priority of U.S. Provisional Patent Application Ser. No. 62/538,994, filed Jul. 31, 2017. The entire content of this application is hereby incorporated by reference herein.

### STATEMENT REGARDING FEDERALLY SPONSORED RESEARCH OR DEVELOPMENT

This invention was made with government support under Contract No. DE-FG02-07ER46387 awarded by the U.S. Department of Energy Office of Basic Energy Sciences. The government has certain rights in the invention.

### BACKGROUND OF THE INVENTION

Inorganic LED-based micro-displays are currently manufactured based on two designs. In the three-color LED approach, precise integration and bonding of InGaN (blue and green) and AlGaInP (red) microLEDs has proven to be very difficult. The single-color approach utilizes InGaN blue LEDs paired with phosphors to create white-color backlight and utilizes color filtering to produce an image. This method is hampered by the low absorption coefficient of the phosphor medium, requiring a thick phosphor layer for wavelength conversion and causing pixel-pixel cross-talking.

### SUMMARY OF THE INVENTION

One embodiment of the invention provides an LED device including: a semi-conductive surface including an array of electrical circuits configured to allow for individual electronic control of each circuit; and a plurality of Gallium-Nitride (GaN) diodes disposed on the semi-conductive surface, each of which are in electronic communication with one of the array of electrical circuits, and each of which are electronically isolated from one another. Each of the GaN diodes includes: at least one p-type GaN (p-GaN) layer proximal to the semi-conductive surface; a multiple quantum well (MQW) region in contact with the p-GaN layer, distal to the semi-conductive surface; and at least one n-type GaN (n-GaN) layer in contact with the MQW region, distal to the p-GaN layer and the semi-conductive surface. The n-GaN layer of at least some of the GaN diodes is electrochemically etched and impregnated with color-conversion quantum dots. The color-conversion quantum dots are impregnated within discrete subsets of the GaN diodes.

This aspect of the invention can have a variety of embodiments. The plurality of GaN diodes can be monochromatic blue LEDs. A subset of the electrochemically etched n-GaN layer surfaces can be embedded with a red quantum dot composition. A subset of the electrochemically etched n-GaN layer surfaces can be embedded with a green quantum dot composition.

The plurality of GaN diodes can be monochromatic blue LEDs. A first portion of the plurality of GaN diodes can include electrochemically etched n-GaN layer nanoporous surfaces and can be embedded with a red light emitting quantum dot composition. A second portion of the plurality of GaN diodes can include electrochemically etched n-GaN layer nanoporous surfaces and can be embedded with a green light emitting quantum dot composition. A third portion of the plurality of GaN diodes can include either un-etched n-GaN layer surfaces or electrochemically etched n-GaN layer nanoporous surfaces that do not include any embedded quantum dots. The first portion, second portion and third portion can be evenly distributed across the semi-conductive surface. The plurality of GaN diodes can be arranged as an array of pixels, each pixel including an equal number of diodes of the first portion, second portion and third portion of GaN diodes.

At least a portion of the electrochemically etched n-GaN layer surfaces can be embedded with one or more CdSe colloidal quantum dot compositions.

The semi-conductive surface can include a silicon wafer.

The semi-conductive surface can include a complementary metal-oxide-semiconductor (CMOS) driver.

The plurality of GaN diodes can be attached to the semi-conductive surface through a metal bonding process. The plurality of GaN diodes can be attached to the semi-conductive surface through indium metal bonding.

The LED device can further include an insulator disposed between the plurality of GaN diodes. The insulator can include a material selected from the group consisting of glasses, polymers, and ceramics.

The LED device can further include segments of transparent conductive glass disposed on the n-GaN surface of the GaN diodes distal to the semi-conductive surface. The transparent conductive glass can be an indium tin oxide glass. The LED device can further include a ground electrode in electrical communication with the segments of transparent conductive glass disposed on the plurality of GaN diodes. The ground electrode can be an indium tin oxide electrode.

The LED device can further include a transparent glass covering over the plurality of GaN diodes, distal to the semi-conductive surface.

The plurality of GaN diodes can include two or more n-GaN layers. Each of the GaN diodes can include: a first n-GaN layer doped for optimal conductivity in contact with the MQW region, and a second n-GaN layer doped for optimal electrochemical etching porosity in contact with the first n-GaN layer.

The quantum dot particle compositions can be attached to the surface of the nanoporous n-GaN layer through the use of an adhesive.

The lateral dimension of the diodes is between about 5 μm and about 100 μm.

The electrochemically etched nanoporous n-GaN layer can include nanopores having a thickness between about 0.1 μm and about 5 μm.

Another aspect of the invention provides a method of making an LED device. The method includes: (a) forming a semi-conductive surface comprising an array of electrical circuits configured to allow for individual electronic control of each circuit; (b) bonding a plurality of Gallium Nitride (GaN) diodes to the semi-conductive surface, such that each GaN diode is in electronic communication with one of the array of electrical circuits, and each of which are electronically isolated from one another in order to form a diode array, wherein the GaN diodes comprise: at least one p-type GaN (p-GaN) layer proximal to the semi-conductive surface, a multiple quantum well (MQW) region in contact with the p-GaN layer, distal to the semi-conductive surface, and at least one n-type GaN (n-GaN) layer in contact with the MQW region, distal to the p-GaN layer and the semi-conductive surface; (c) performing either step (I) or step (II). Step (I) includes: (i) coating the diode array with a photoresist material; (ii) selectively removing segments of photoresist material covering a portion of the GaN diodes, exposing the surface of the n-GaN layer; (iii) electrochemically etching the exposed n-GaN surface to create a nanoporous surface; (iv) contacting the exposed nanoporous surface with a quantum dot-containing solution to impregnate the quantum dots into the nanoporous layer; and (v) optionally repeating sub-steps (i)-(iv). Step (II) includes: (i) bonding a monolithic n-GaN layer distally to the n-GaN layers; (ii) electrochemically etching at least a portion of a distal surface of the monolithic n-GaN surface to create a nanoporous surface; (iii) coating the monolithic n-GaN layer with a photoresist material; (iv) selectively removing segments of photoresist material covering a portion of the GaN diodes, exposing the surface of the nanoporous monolithic n-GaN layer; (v) contacting the exposed nanoporous surface with a quantum dot composition; and (vi) optionally repeating sub-steps (iii)-(v).

This aspect of the invention can have a variety of embodiments. Step (II) can further include selectively removing portions of the monolithic n-GaN that are not disposed on top of a GaN diode.

The method can further include: (d) removing all photoresist material; (e) adding an insulator disposed between the plurality of GaN diodes; (f) coating the diode array with a photoresist material; (g) selectively removing segments of photoresist material which cover each GaN diode, exposing the n-GaN surface; and (h) depositing a layer of transparent conducting glass on the exposed n-GaN surface of each diode. The transparent conducting glass can be a layer of titanium/indium tin oxide (Ti/ITO). The method can further include (i) depositing a ground electrode layer on the transparent conducting glass layer of each diode, such that the ground electrode layer forms a continuous contact with all GaN-diodes. The ground electrode layer can be an indium tin oxide (ITO) layer. The method can further include (j) mounting a glass substrate layer on the ground electrode layer. The insulator can be selected from the group consisting of glasses, polymers, and ceramics.

The electrochemical etching step can include contacting the exposed n-GaN surface with an oxalic acid solution and subjecting the n-GaN layer to a positive electrical potential of about 15 V to about 25 V for about 60 seconds.

The electrochemically etched nanoporous n-GaN layer can include nanopores having a depth of about 2 μm.

The quantum dot composition can be a CdSe colloidal quantum dot composition, a green quantum dot composition, and/or a red quantum dot composition.

Step (I)(v) or step (II)(vi) can be performed at least once. In one instance of steps (I)(ii-iv) or steps (II)(iv-v), a first portion of n-GaN layers can be contacted with a red quantum dot composition and, in another distinct instance of steps (I)(ii-iv) or (II)(iv-v), a second portion of n-GaN layers can be contacted with a green quantum dot composition.

At least a third portion of the plurality of GaN diodes may not contacted by a quantum dot composition. The first portion, second portion, and third portion can be evenly distributed across the semi-conductive surface. The plurality of GaN diodes are arranged as an array of pixels. Each pixel can include an equal number of diodes of the first portion, second portion and third portion of GaN diodes.

The semi-conductive surface can include a complementary metal-oxide-semiconductor (CMOS) driver. The plurality of GaN diodes can be attached to the semi-conductive surface through a metal bonding process. The plurality of GaN diodes can be attached to the semi-conductive surface through indium metal bonding.

The GaN diodes can have a maximum cross-sectional dimension between about 2 nm and about 50 nm.

Steps (I)(iv) or (II)(v) can further include using an adhesive to attach the quantum dot particle compositions to the surface of the nanoporous n-GaN layer.

The photoresistive material can be removed through photolithography.

### BRIEF DESCRIPTION OF THE DRAWINGS

For a fuller understanding of the nature and desired objects of the present invention, reference is made to the following detailed description taken in conjunction with the accompanying drawing figures wherein like reference characters denote corresponding parts throughout the several views.

FIGS. 1A and 1B depict LED devices having three distinct diode varieties, according to an embodiment of the invention.

FIGS. 2A-2E depict a first method of fabricating a LED device according to an embodiment of the invention.

FIGS. 3A-3F depict a second method of fabricating a LED device according to an embodiment of the invention.

FIGS. 4A-4E are images showing the incorporation of colloidal quantum dots (CQDs) into a nanoporous GaN (NP-GaN) host material. FIG. 4A is a set of photographic images of visual transparency as evidence for the incorporation of CdSe/SnCdS core/shell CQDs into the NP-GaN matrix. FIGS. 4B and 4C are top-view SEM images of the NP-GaN (FIG. 4B) and CQD/NP-GaN (FIG. 4C). FIGS. 4D and 4E are cross-sectional SEM images of NP-GaN (FIG. 4D) and CQD/NP-GaN (FIG. 4E). The circles highlight the high-density absorption of CQDs onto the sidewalls of the nanopores in the nanocomposite structures.

FIG. 4F is a graph of the photoluminescence of CQD/NP-GaN nanocomposite materials of varying pore sizes compared with bulk GaN.

FIG. 4G is a graph showing the photoluminescence spectrum of the starting CQD solution mixture and the spectrum of a solid CQD/NP-GaN nanocomposite thin film. The inset image is a photograph of the CQD/NP-GaN nanocomposite emission.

FIG. 5A is a set of images depicting a top-view (top) and cross-sectional (bottom) SEM depiction of the N-face GaN layer that has been vertically porosified from the top surface with a 0.7 μm depth under continuous etching conditions, according to an embodiment of the invention.

FIG. 5B is a set of images depicting a top-view (top) and cross-sectional (bottom) SEM depiction of the N-face GaN layer that has been vertically porosified from the top surface with a 1.0 μm depth under pulsed etching conditions, according to an embodiment of the invention.

### DEFINITIONS

The instant invention is most clearly understood with reference to the following definitions.

As used herein, the singular form “a,” “an,” and “the” include plural references unless the context clearly dictates otherwise.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from context, all numerical values provided herein are modified by the term about.

As used in the specification and claims, the terms “comprises,” “comprising,” “containing,” “having,” and the like can have the meaning ascribed to them in U.S. patent law and can mean “includes,” “including,” and the like.

Unless specifically stated or obvious from context, the term “or,” as used herein, is understood to be inclusive.

Ranges provided herein are understood to be shorthand for all of the values within the range. For example, a range of 1 to 50 is understood to include any number, combination of numbers, or sub-range from the group consisting 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50 (as well as fractions thereof unless the context clearly dictates otherwise).

The following abbreviations are used herein:
CQDs Colloidal Quantum Dots
EC Electrochemical
IC Individual Control
LED(s) Light Emitting Diode(s)
MQW Multiple Quantum Well
NP-GaN Nanoporous Gallium Nitride

### DETAILED DESCRIPTION OF THE INVENTION

Embodiments of the present invention provide LED devices including an array of individually controlled gallium-nitride-based diodes, at least a portion of which have been electrochemically etched and impregnated with quantum dot formulations. The invention further provides methods of making such LED devices.

The gallium nitride (GaN) described herein, whether p-type or n-type, can be non-polar, semi-polar, or c-plane GaN.

### LED Devices

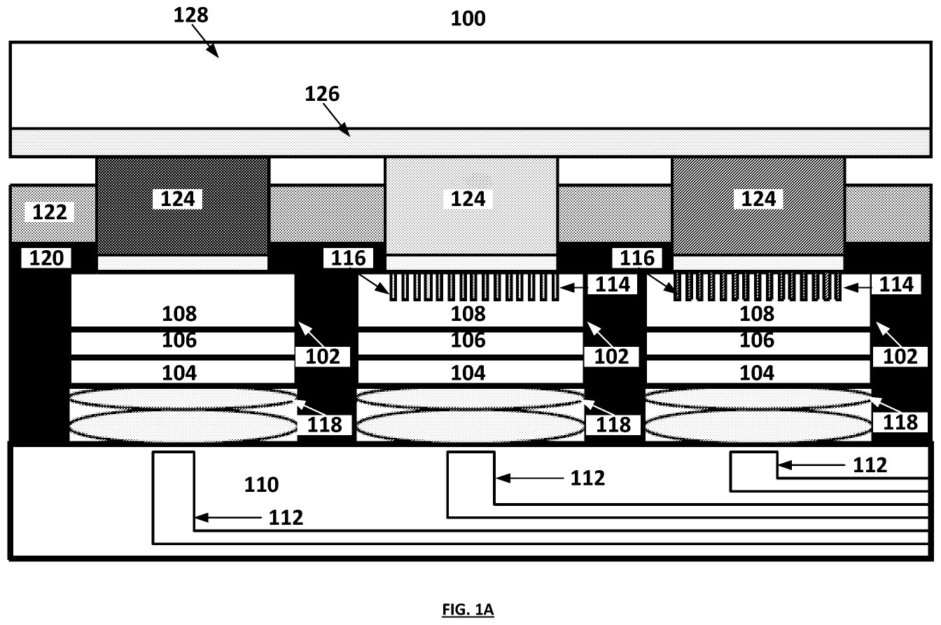

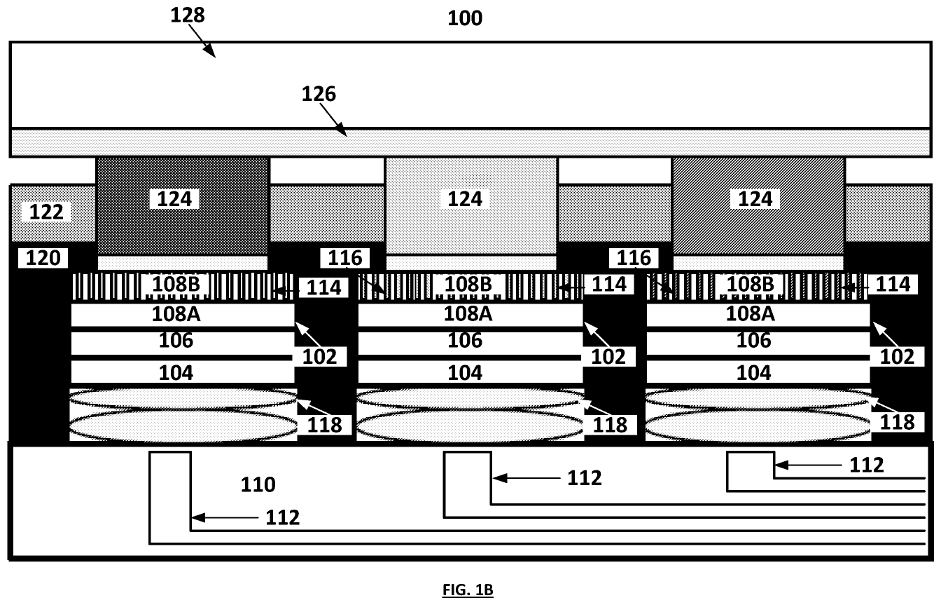

Referring to FIGS. 1A and 1B, the invention provides an LED device 100 that includes an array of substantially identical GaN based LED diodes 102. The GaN diodes 102 can have multiple layers, including at least one p-type GaN (p-GaN) layer 104, a multiple quantum well region 106 and at least one n-type GaN (n-GaN) layer 108. The GaN diodes 102 can be mounted on a semi-conductive surface 110, comprising an array of electrical circuits 112 configured to allow for individual electronic control of each circuit 112.

At least a portion of the GaN diodes 102 can be selectively modified to allow for impregnation of the n-GaN layer 108 with one or more quantum dot formulations in order to produce a range of colored emissions. At least a portion of the n-GaN layers 108 can be electrochemically etched in order to produce a nanoporous n-GaN surface layer 114. Nanoporous n-GaN surface layer 114 can be absent in a portion of GaN diodes 102. At least some of the GaN diodes 102 that have been electrochemically etched in order to produce a nanoporous n-GaN surface layer 114 can be impregnated with compositions comprising quantum dots 116. In select embodiments, the quantum dots 116 can be attached to the nanoporous n-GaN surface layer 114 through the use of an adhesive.

The unmodified GaN diodes 102 of the invention can be monochromatic blue LEDs (e.g., emitting light at a wavelength of about 450 nm to about 495 nm). In order to produce additional colors of light, quantum dots 116 having various properties can be impregnated in the nanoporous n-GaN surface layers 114. Red quantum dots (e.g., emitting light at a wavelength of about 620 nm to about 750 nm), and green quantum dots (e.g., emitting light at a wavelength of about 495 nm to about 570 nm) can be utilized in tandem with the unmodified monochromatic blue LED in order to produce a broad array of colors via the additive RGB color model. However, the invention includes alternative embodiments, wherein the GaN diodes can be designed and modified according to methods well understood by those of ordinary skill in the art to emit light of any wavelength desired.

In some embodiments: a first portion of the plurality of GaN diodes 102 includes an electrochemically etched n-GaN layer 114 having at least one nanoporous surface and embedded with a red-light-emitting quantum dot composition; a second portion of the plurality of GaN diodes 102 includes an electrochemically etched n-GaN layer 114 having at least one nanoporous surfaces and embedded with a green-light-emitting quantum dot composition; and a third portion of the plurality of GaN diodes 102 include either an un-etched n-GaN layer 108 surfaces or electrochemically etched n-GaN layer 114 nanoporous surfaces that does not include any embedded quantum dots. The first portion, second portion and third portion can be evenly distributed across the semi-conductive surface 110 and arranged as an array of pixels, each pixel including an equal number of diodes 102 of the first portion, second portion and third portion of GaN diodes 102.

The n-GaN layers described herein can be formed using the technique described in C. Dang et al., “A Wafer-Level Integrated White-Light-Emitting Diode Incorporating Colloidal Quantum Dots as a Nanocomposite Luminescent Material”, 24 Adv. Mater. 5915-18 (2012).

The quantum dot compositions can include any quantum dots known in the art to produce light of the desired wavelength. For example, the n-GaN layer surfaces can be embedded with one or more CdSe colloidal quantum dot compositions, wherein the size of the quantum dots themselves are varied to produce different colors of light. The quantum dots compositions can include monodispersed quantum dots of substantially uniform size and chemical composition. Alternatively, the quantum dot compositions can comprise a mixture of two or more quantum dot varieties. In certain embodiments, the quantum dots can have a maximum cross-sectional dimension between about 2 nm and about 50 nm.

In certain embodiments, the GaN diodes 102 are bound to the semi-conductive surface 110 through a metal bonding process, forming a metal bonding layer 118. The metal bonding process can be indium metal bonding.

The semi-conductive surface 110 can be fabricated from a range of semi-conducting materials, such as, but not limited to, silicon, plastics, and polymeric materials. The semi-conducting materials can be rigid, semi-rigid, or flexible. In certain embodiments, the semi-conductive surface 110 comprises a complementary metal-oxide semiconductor (CMOS) driver. The electrical circuits 112 can be made of any electrically conductive material known in the art to be useable as part of a circuit board. For example, the electrical circuits 112 can comprise copper wires.

The LED device can further comprise one or more insulator layers 120, 122 disposed between the GaN diodes 102. The insulator layers can be a photoresist material, such as, but not limited to, glasses, polymers, and ceramics.

The LED device can also comprise segments of conducting glass 124 disposed on the n-GaN surface 114 of the GaN diodes 102, distal to the semi-conductive surface 110. One or more insulator layers 122 can be disposed between the glass segments 124, optically and/or electronically isolating the conducting glass segments 124 from one another, and preventing cross-talk between GaN diodes 102. Conducting glass 124 and/or insulator layers 122 can collimate light emitted by the LEDs 102. In certain embodiments, the conducting glass segments 124 can be composed of titanium/indium tin oxide (Ti/ITO) glass. The LED device can further include a ground electrode 126 in electrical communication with the glass segments 124. The ground electrode 126 can bridge the span between glass segments 124 and act as a ground for the current introduced via circuits 112. In certain embodiments, the ground electrode 126 can be composed of ITO glass.

The LED device can further include at least one transparent glass covering 128 over the plurality of GaN diodes 102, distal to the semi-conductive surface. The transparent glass covering 128 can be fully transparent or partially transparent. The transparent glass covering 128 can have one or more qualities, such as but not limited to, being scratchproof, scratch resistant, shatter resistant, heat resistant, flexible, electrically conductive and/or resistant, providing polarized light filtering, and/or color tinting. A variety of outer glass layers are used in displays such as smartphones, tablets, televisions, and other displays, and can be applied to embodiments of the invention.

In certain embodiments, the individual GaN diodes 102 can have a maximum lateral dimension between about 5 μm to about 100 μm. The electrochemically etched nanoporous n-GaN layer 114 can include nanopores having a depth between about 0.1 μm to about 5 μm.

Referring now to FIG. 1B, the GaN diodes 102 can comprise two n-GaN layers: a first n-GaN layer 108A doped for optimal conductivity in contact with the MQW region, and a second n-GaN layer 108B doped for optimal electrochemical etching porosity in contact with the first n-GaN layer 108A. The second n-GaN layer 108B can have the etched n-GaN surface 114 and be impregnated with the quantum dots 116.

### Fabrication Methods

The invention also provides methods of fabricating the LED devices 100 of the invention, described elsewhere herein.

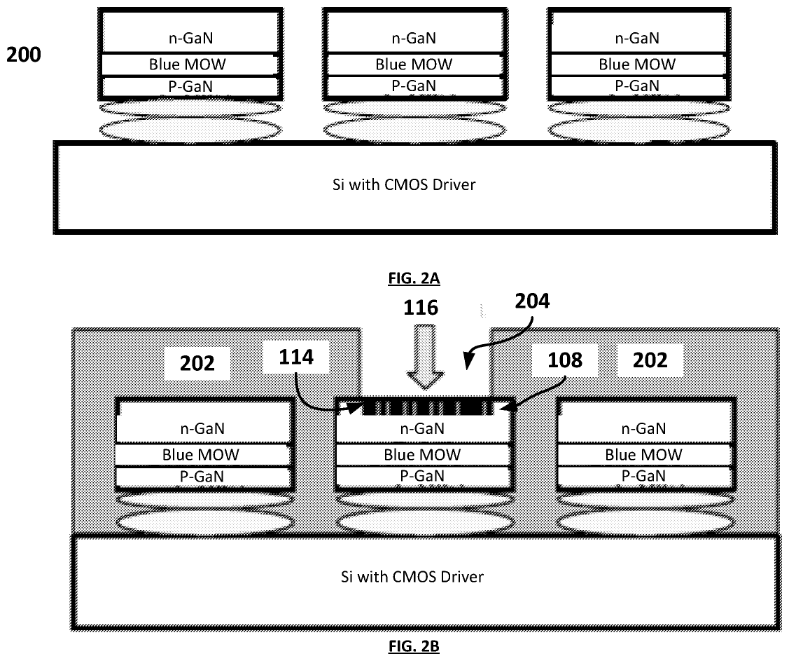

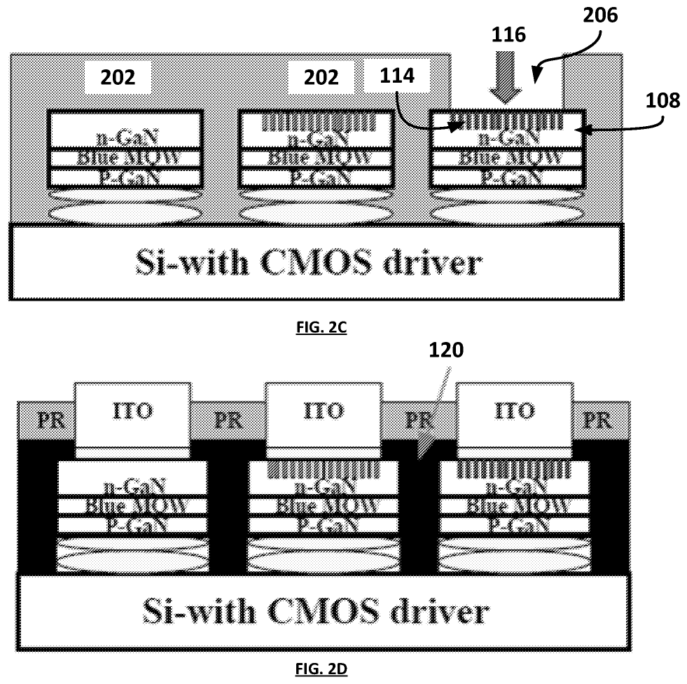

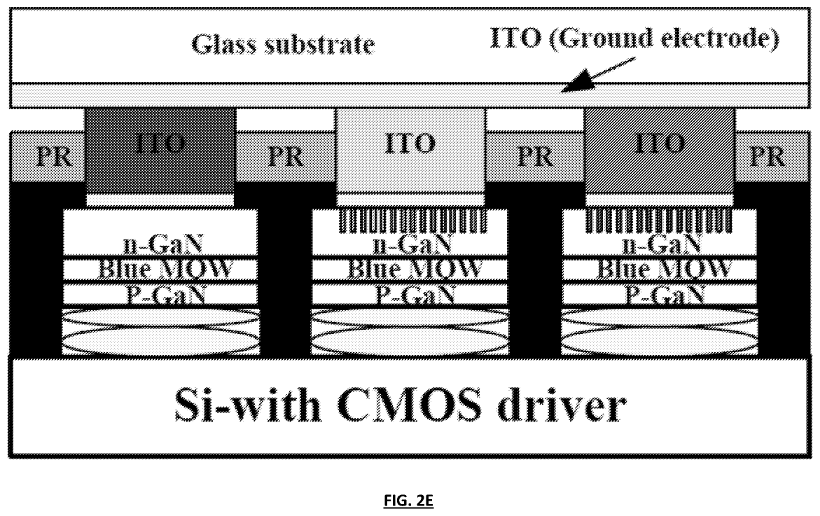

Referring to FIGS. 2A-2E, one method of fabricating the LED devices 100 of the invention can include first forming a semi-conductive surface 110 including an array of electrical circuits 112 configured to allow for individual electronic control of each circuit, followed by bonding a plurality of gallium nitride (GaN) diodes 102 to the semi-conductive surface 112, such that each GaN diode is in electronic communication with one of the array of electrical circuits 112, and each of which are electronically isolated from one another in order to form a diode array 200 (FIG. 2A). Each GaN diode 102 can include at least one p-type GaN (p-GaN) layer 104 proximal to the semi-conductive surface 110, a multiple quantum well (MQW) region 106 in contact with the p-GaN layer 104, distal to the semi-conductive surface 110, and at least one n-type GaN (n-GaN) layer 108/108A in contact with the MQW region 106, distal to the p-GaN layer 104 and the semi-conductive surface 110, as described elsewhere herein. The GaN diodes 102 can be secured to the semi-conductive surface 110 through metal bonding, for instance, through indium metal bonding.

After the GaN diodes 102 have been secured to the semi-conductive surface 110, the LED device 100 can be fabricated through one of two approaches.

Referring to FIGS. 2B and 2C, the first approach includes coating the diode array 200 with a photoresist material 202, and selectively removing segments of photoresist material 204, 206, exposing the surface of the n-GaN layer 108. The exposed surface of the select n-GaN layers 108 can then be electrochemically etched to create nanoporous n-GaN surface layers 114. The nanoporous n-GaN surface layers 114 can then be contacted with a quantum-dot-containing solution to impregnate the quantum dots 116 into the nanoporous n-GaN surface layers 114. This approach can be repeated multiple times, removing different segments of photoresist material 204, 206, as shown in FIGS. 2B and 2C, each time contacting distinct sub-sets of GaN diodes 102 with a different quantum dot 116 containing solution. For example, in a first instance, a first portion of GaN diodes 102 can be contacted with red nanoparticles and, in a second instance, a second portion of GaN diodes 102 can be contacted with green nanoparticles.

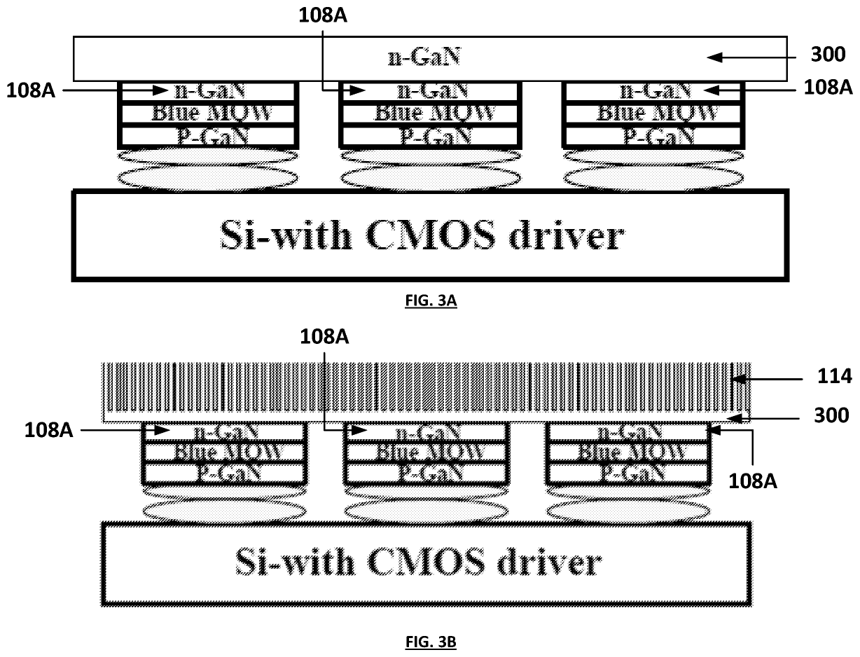

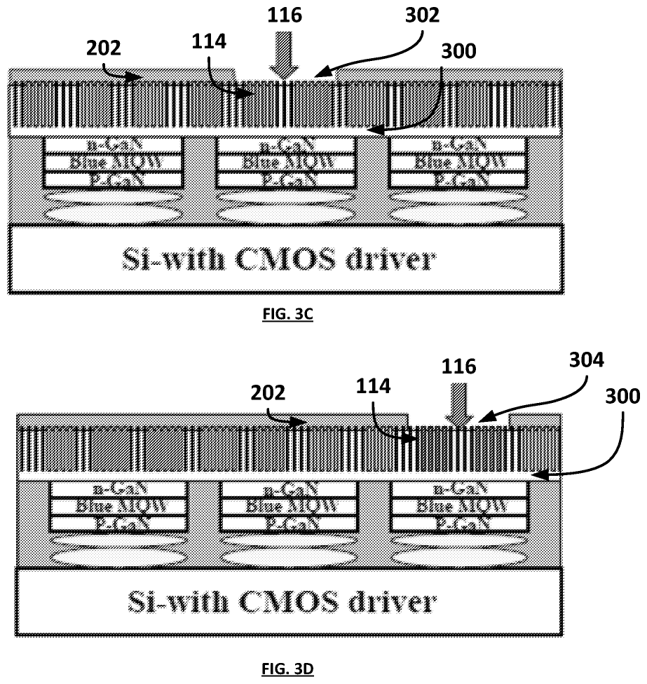

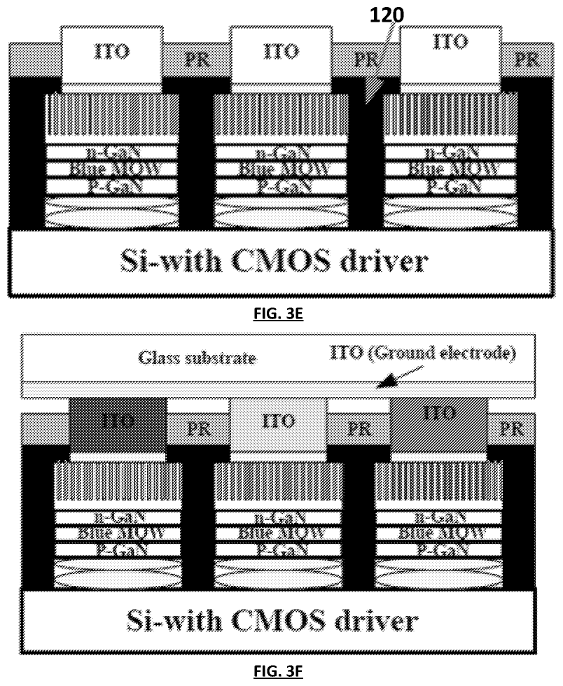

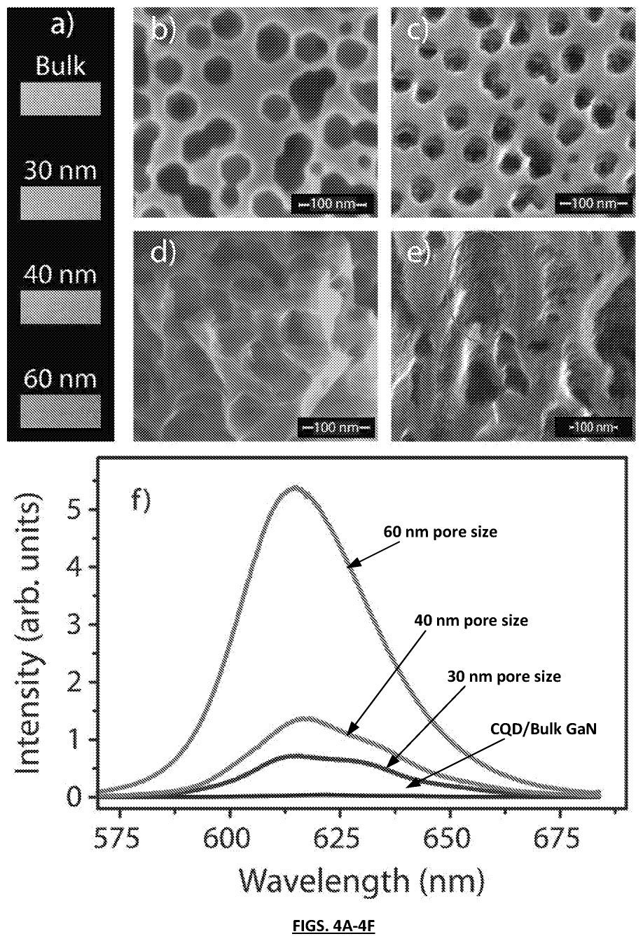

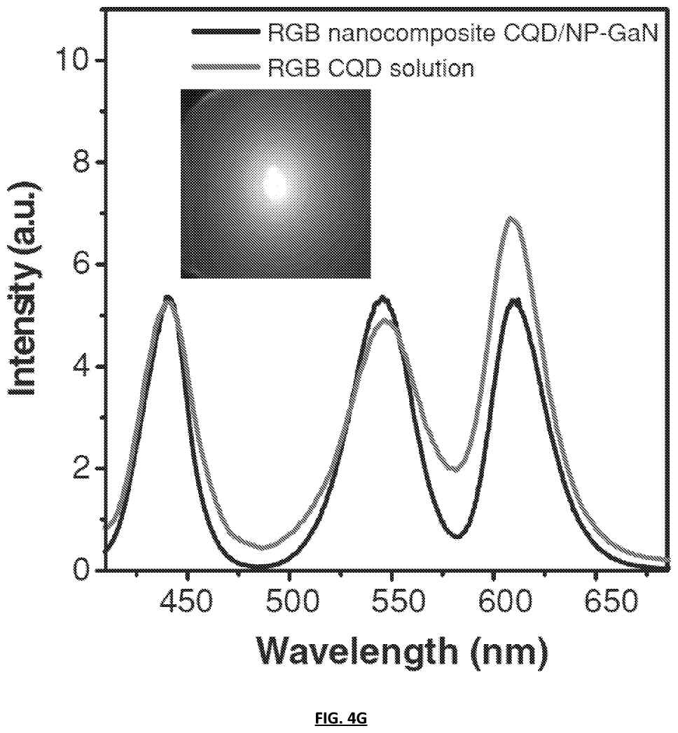

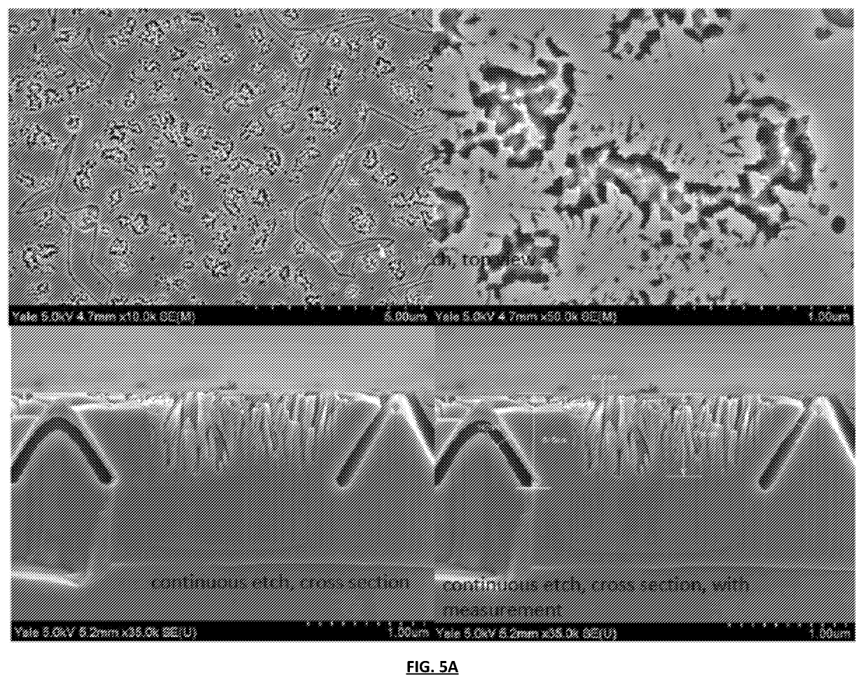

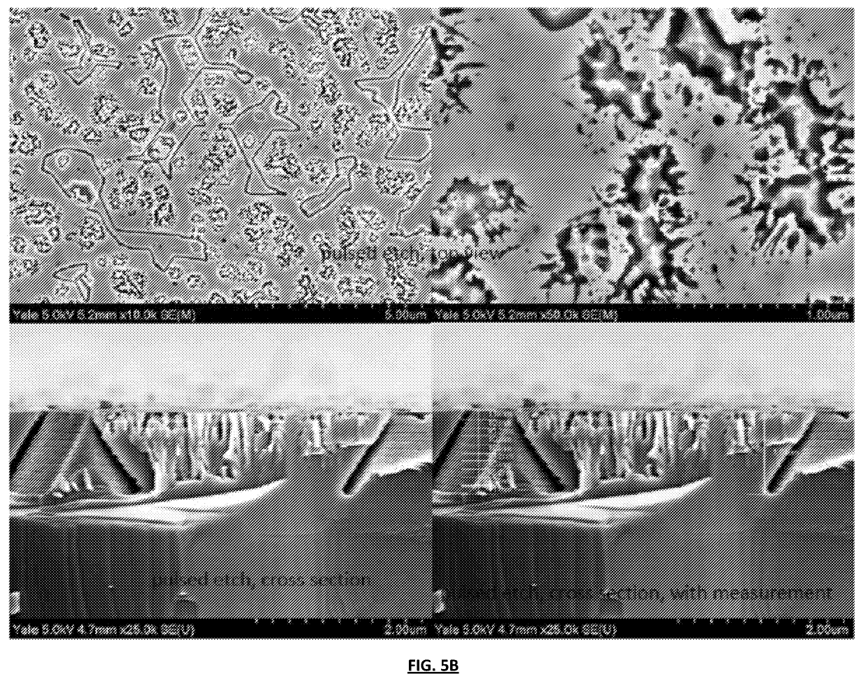

Referring to FIGS. 3A-3D, the second approach utilizes a monolithic n-GaN layer 300 distal to the n-GaN layers 108A (FIG. 3A). The embodiment depicted in FIG. 3A can be produced through bonding an LED wafer on sapphire (with 108A and 300) to a Si CMOS driver wafer, followed by laser lift-off (LLO) or other liftoff process to separate/sever the sapphire and the n-GaN layer 300. (In this sense, FIG. 2A can be derived from FIG. 3A, but first with a dry etching to separate individual LED dies before proceeding to FIG. 2B.)

At least a portion of a distal surface of the monolithic n-GaN layer 300 can be electrochemically etched to create the nanoporous n-GaN surface layer 114 (FIG. 3B). The method further includes coating the diode array 200 with a photoresist material 202, and selectively removing segments of photoresist material 302, 304, exposing select portions of the surface of the nanoporous n-GaN surface layer 114 that are disposed on top of at least a portion of the GaN diodes 102. The exposed nanoporous n-GaN surface layer 114 can then be contacted with a quantum-dot-containing solution to impregnate the quantum dots 116 into the nanoporous n-GaN surface layers 114. This approach can be repeated multiple times, removing different segments of photoresist material 302, 304, as shown in FIGS. 3C and 3D, each time contacting distinct sub-sets of GaN diodes 102 with a different quantum dot 116 containing solution. For example, in a first instance, a first portion of GaN diodes 102 can be contacted with red nanoparticles and, in a second instance, a second portion of GaN diodes 102 can be contacted with green nanoparticles. Portions of the monolithic n-GaN layer 300 that are not disposed on top of a GaN diode 102 can be selectively removed after first fully removing the photoresist material 202, thereby creating individual n-GaN layers 108B.

In either approach, various techniques such as vibration (e.g., ultrasound), cavitation, pressure, vacuum, and the like can be utilized to promote migration of the quantum dots within the nanopores.

Referring to FIGS. 2D and 2E and FIGS. 3E and 3F, the first approach and second approach converge and the fabrication methods can further include fully removing all photoresist material 202 and adding an insulator layer 120 disposed between the plurality of GaN diodes 102. The diode array 200 can then be further coated with a photoresist material 202, forming a second insulating layer 122. Segments of the second insulating layer 122 that cover each GaN diode 102 can then be removed, exposing the n-GaN layers 108/nanoporous n-GaN surface layers 114. Segments of transparent conducting glass 124 can be deposited on the exposed n-GaN layers 108/nanoporous n-GaN surface layers 114 of each diode. A ground electrode layer 126 can then be deposited on the segments of conducting glass 124, such that the ground electrode layer 126 forms a continuous contact with all GaN diodes 102. The method can also comprise mounting a glass substrate 128 on the ground electrode 126.

In certain embodiments of the etching steps, the electrochemical etching step includes contacting the exposed n-GaN surface with an oxalic acid solution and subjecting the n-GaN layer to a positive electrical potential of about 15 V to about 25 V for about 60 seconds.

In certain embodiments of the methods, the contacting of the nanoporous n-GaN surface layers 114 with the quantum dot 116 can further include the use of an adhesive. For example, the quantum dots 116 can be suspended within a solution (e.g., a polyurethane solution) that will bind the quantum dots 116 within the nanoporous n-GaN surface layers 114 after a solvent evaporates, upon curing, upon crosslinking, and the like.

In certain embodiments of the methods, the photoresist materials 202 can be removed through photolithography.

### EQUIVALENTS

Although preferred embodiments of the invention have been described using specific terms, such description is for illustrative purposes only, and it is to be understood that changes and variations may be made without departing from the spirit or scope of the following claims.

### INCORPORATION BY REFERENCE

The entire contents of all patents, published patent applications, and other references cited herein are hereby expressly incorporated herein in their entireties by reference.

1. An LED device comprising:
a semi-conductive surface comprising an array of electrical circuits configured to allow for individual electronic control of each circuit; and
a plurality of Gallium-Nitride (GaN) diodes disposed on the semi-conductive surface, each of which are in electronic communication with one of the array of electrical circuits, and each of which are electronically isolated from one another;
each of the GaN diodes comprising:
at least one p-type GaN (p-GaN) layer proximal to the semi-conductive surface;
a multiple quantum well (MQW) region in contact with the p-GaN layer, distal to the semi-conductive surface; and
at least one n-type GaN (n-GaN) layer in contact with the MQW region, distal to the p-GaN layer and the semi-conductive surface;
wherein the n-GaN layer of at least some of the GaN diodes is electrochemically etched and impregnated with color-conversion quantum dots, wherein the color-conversion quantum dots are impregnated within discrete subsets of the GaN diodes.

2. (canceled)

3. The LED device of claim 1, wherein a subset of the electrochemically etched n-GaN layer surfaces are embedded with a red quantum dot composition or a green quantum dot composition.

4. (canceled)

5. The LED device of claim 1, wherein:
the plurality of GaN diodes are monochromatic blue LEDs;
a first portion of the plurality of GaN diodes comprise electrochemically etched n-GaN layer nanoporous surfaces and are embedded with a red light emitting quantum dot composition;
a second portion of the plurality of GaN diodes comprise electrochemically etched n-GaN layer nanoporous surfaces and are embedded with a green light emitting quantum dot composition; and
a third portion of the plurality of GaN diodes comprise either un-etched n-GaN layer surfaces or electrochemically etched n-GaN layer nanoporous surfaces that do not comprise any embedded quantum dots.

6. (canceled)

7. The LED device of claim 5, wherein the plurality of GaN diodes are arranged as an array of pixels, each pixel comprising an equal number of diodes of the first portion, second portion and third portion of GaN diodes.

8. The LED device of claim 1, wherein at least a portion of the electrochemically etched n-GaN layer surfaces are embedded with one or more CdSe colloidal quantum dot compositions.

9. The LED device of claim 1, wherein the semi-conductive surface comprises a silicon wafer.

10. The LED device of claim 1, wherein the semi-conductive surface comprises a complementary metal-oxide-semiconductor (CMOS) driver.

11. The LED device of claim 1, wherein the plurality of GaN diodes are attached to the semi-conductive surface through a metal bonding process.

12. The LED device of claim 11, wherein the plurality of GaN diodes are attached to the semi-conductive surface through indium metal bonding.

13. The LED device of claim 1, further comprising an insulator disposed between the plurality of GaN diodes.

14. (canceled)

15. The LED device of claim 1, further comprising segments of transparent conductive glass disposed on the n-GaN surface of the GaN diodes distal to the semi-conductive surface.

16. The LED device of claim 15, wherein the transparent conductive glass is an indium tin oxide glass.

17. The LED device of claim 15, further comprising a ground electrode in electrical communication with the segments of transparent conductive glass disposed on the plurality of GaN diodes.

18. The LED device of claim 17, wherein the ground electrode is an indium tin oxide electrode.

19. The LED device of claim 1, further comprising a transparent glass covering over the plurality of GaN diodes, distal to the semi-conductive surface.

20. The LED device of claim 1, wherein the plurality of GaN diodes comprise two or more n-GaN layers.

21. The LED device of claim 20, wherein each of the GaN diodes comprise:
a first n-GaN layer doped for optimal conductivity in contact with the MQW region, and
a second n-GaN layer doped for optimal electrochemical etching porosity in contact with the first n-GaN layer.

22. (canceled)

23. The LED device of claim 1, wherein the lateral dimension of the diodes is between about 5 μm and about 100 μm.

24. The LED device of claim 1, wherein the electrochemically etched nanoporous n-GaN layer comprises nanopores having a thickness between about 0.1 μm and about 5 μm.

25. A method of making an LED device, the method comprising:
(a) forming a semi-conductive surface comprising an array of electrical circuits configured to allow for individual electronic control of each circuit;
(b) bonding a plurality of Gallium Nitride (GaN) diodes to the semi-conductive surface, such that each GaN diode is in electronic communication with one of the array of electrical circuits, and each of which are electronically isolated from one another in order to form a diode array, wherein the GaN diodes comprise:
at least one p-type GaN (p-GaN) layer proximal to the semi-conductive surface,
a multiple quantum well (MQW) region in contact with the p-GaN layer, distal to the semi-conductive surface, and
at least one n-type GaN (n-GaN) layer in contact with the MQW region, distal to the p-GaN layer and the semi-conductive surface;
(c) performing either step (I) or step (II):
(I)
(i) coating the diode array with a photoresist material;
(ii) selectively removing segments of photoresist material covering a portion of the GaN diodes, exposing the surface of the n-GaN layer;
(iii) electrochemically etching the exposed n-GaN surface to create a nanoporous surface;
(iv) contacting the exposed nanoporous surface with a quantum dot-containing solution to impregnate the quantum dots into the nanoporous layer; and
(v) optionally repeating sub-steps (i)-(iv);
(II)
(i) bonding a monolithic n-GaN layer distally to the n-GaN layers;
(ii) electrochemically etching at least a portion of a distal surface of the monolithic n-GaN surface to create a nanoporous surface;
(iii) coating the monolithic n-GaN layer with a photoresist material;
(iv) selectively removing segments of photoresist material covering a portion of the GaN diodes, exposing the surface of the nanoporous monolithic n-GaN layer;
(v) contacting the exposed nanoporous surface with a quantum dot composition; and
(vi) optionally repeating sub-steps (iii)-(v).

26.-37. (canceled)
